(19) United States
(12) Patent Application Publication
(10) Pub. No.: US 2007/0161255 A1
(43) Pub. Date: Jul. 12, 2007

(54) METHOD FOR ETCHING WITH HARDMASK

(76) Inventors: Wilfred Pau, Santa Clara, CA (US); Meihua Shen, Fremont, CA (US)

Correspondence Address: PATTERSON & SHERIDAN, LLP, 3040 POST OAK BOULEVARD, SUITE 1500, HOUSTON, TX, 77056, US

(21) Appl. No.: 11/620,271

(22) Filed: Jan. 5, 2007

Related U.S. Application Data
(60) Provisional application No. 60/757,209, filed on Jan. 6, 2006.

(51) Int. Cl. H01L 21/31

(52) U.S. Cl. 438/778

(57) ABSTRACT

Methods are provided for processing a substrate by depositing a hardmask material on a surface of the substrate, depositing an anti-reflective coating on the hardmask material, depositing a resist material on the anti-reflective coating, patterning the resist material to form a first resist features having a first width to expose the anti-reflective coating, etching the anti-reflective coating and a first portion of the hardmask material, and trimming the resist material to form a second resist feature having a second width less than the first width.

### CROSS-REFERENCE TO RELATED APPLICATIONS

This application claims benefit of U.S. provisional patent application Ser. No. 60/757,209 (APPM/010578L), filed Jan. 6, 2006, which is herein incorporated by reference.

### BACKGROUND OF THE DISCLOSURE

1. Field of the Invention

The invention relates to the fabrication of integrated circuits and to a process for forming feature definitions on substrate surfaces.

2. Description of the Related Art

To increase operational speed of devices (e.g., transistors, capacitors, and the like) in integrated microelectronic circuits, the device features have become ever smaller. The minimal dimensions of features of such devices are commonly called in the art, critical dimensions, or CDs. The CDs generally include the minimal widths of the features, such as lines, columns, openings, spaces between the lines, and the like. One method of fabricating such features comprises forming a patterned hardmasks on a material layer, and then etching the material layer using the hardmasks.

Referring to FIGS. 1A-1D, the hardmask is conventionally fabricated using a lithographic process when a pattern of the feature to be formed is optically transferred into a photoresist layer 130 deposited on an optional anti-reflective coating (ARC) layer 120 deposited on a hardmasks 110 material disposed on the substrate 100 in which the features are to be formed. When the ARC layer 120 lies beneath the photoresist layer, the ARC layer 120 is commonly referred to as a bottom anti-reflective coating (BARC). Anti-reflective coatings are used in combination with DUV photoresists, among other photoresists, to reduce standing waves and back-scattered light, so that the dimensions of the patterning in the photoresist can be better controlled. The photoresist is developed and unexposed portions of the photoresist are removed, while the remaining photoresist forms a patterned mask as shown in FIG. 1A.

A hardmasks 110, also known as an etch mask, generally is, a replica of the feature definitions to be formed (i.e., etched) in the underlying layer. As such, the hardmasks comprise elements having the same critical dimensions as the feature to be formed. However, the optical limitations of the lithographic process may not allow transferring a dimensionally accurate image of a feature into the photoresist layer 130 for transfer to the hardmask when a critical dimension of the feature definition to be formed is smaller than optical resolution of the lithographic process.

To overcome limitations of the lithographic process, the photoresist mask may be fabricated using a two-step process. During a first step, the lithographic process is used to form the mask having elements with dimensions that are proportionally greater (i.e., “scaled up”) than the dimensions of the features to be formed as shown in FIG. 1A. During a second step, such “scaled-up” elements are trimmed (i.e., isotropically etched) to the pre-determined dimensions as shown in FIG. 1B. The trimmed photoresist mask is then used as a mask during etching the underlying material layer or layers as shown in FIG. 1C. The photoresist mask material is then removed before etching the underlying substrate 100 using the hardmasks 110 as shown in FIG. 1D.

One problem in trimming such a photoresist mask is the occurrence of critical dimension (CD) microloading, which is a measure of variation in critical dimensions between dense and isolated regions of the substrate after photoresist trimming. The dense regions have a high pattern density of the features and the isolated regions have a low pattern density of the features. Conventional photoresist trimming processes often result in significant CD trimming microloading with the isolated regions being trimmed at much faster rates than dense regions.

Therefore, there is a need in the art for an improved method for controlling photoresist trimming process to reduce microloading effect during fabrication of semiconductor devices in a semiconductor substrate processing system. Therefore, there remains a need for an improved process and material for depositing and patterning dielectric materials for feature formation.

### SUMMARY OF THE INVENTION

Embodiments of the present invention generally provide an improved method for controlling photoresist trimming process to reduce microloading effect during fabrication of semiconductor devices in a semiconductor substrate processing system.

Aspects of the invention generally provide a method of processing a substrate including depositing a hardmask material on a surface of the substrate, depositing an anti-reflective coating on the hardmask material, depositing a resist material on the anti-reflective coating, patterning the resist material to form a first resist features having a first width to expose the anti-reflective coating, etching the anti-reflective coating and a first portion of the hardmask material, and trimming the resist material to form a second resist feature having a second width less than the first width.

In another aspect a method of processing a substrate including depositing a hardmask material on a surface of the substrate, depositing a resist material on the hardmask material, patterning the resist material to form a first resist feature having a first width to expose the hardmask material, etching the anti-reflective coating and a first portion of the hardmask material, trimming the resist material to form a second resist feature having a second width between 10% and 30% less than the first width, etching a second portion of the hardmask material to the surface of the substrate, and removing the resist material.

### BRIEF DESCRIPTION OF THE DRAWINGS

So that the manner in which the above features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-1D are cross sectional views showing a prior art hardmasks opening sequence;

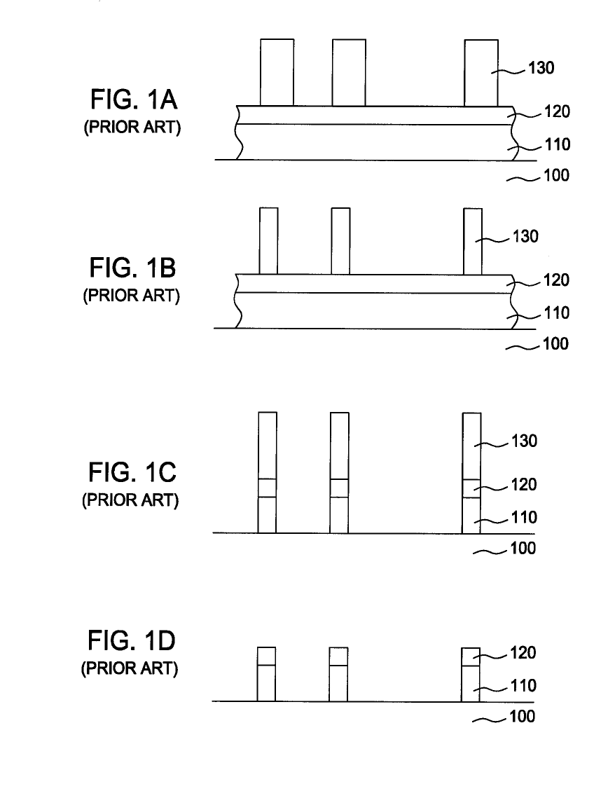

FIG. 2 is a flow chart of one embodiment of a hardmasks opening sequence of the invention; and

FIGS. 3A-3F are cross sectional views showing one embodiment of a hardmasks opening sequence of the invention.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION OF THE PREFERRED EMBODIMENTS

The words and phrases used herein should be given their ordinary and customary meaning in the art by one skilled in the art unless otherwise further defined.

Aspects of the invention described herein refer to method for forming feature definitions, such as line and space or trench and space features by depositing and etching resist and hardmask materials. In one embodiment, the process includes depositing a hardmask material on a surface of the substrate, depositing an anti-reflective coating on the hardmask material, depositing a resist material on the anti-reflective coating, patterning the resist material to form a first resist features having a first width to expose the anti-reflective coating, etching the anti-reflective coating and a first portion of the hardmask material, trimming the resist material to form a second resist feature having a second width less than the first width, etching a second portion of the hardmask material to the surface of the substrate, and removing the resist material.

The etching processes described herein are preferably performed in a processing chamber adapted to chemically etch deposited material while applying RF power, such as DPSII™ AdvantEdge™ Poly Etcher etch chamber or a DPSII™ Poly Etcher etch chamber, all of which are commercially available from Applied Materials, Inc., Santa Clara, Calif.

### Patterning of Line and Space Structure

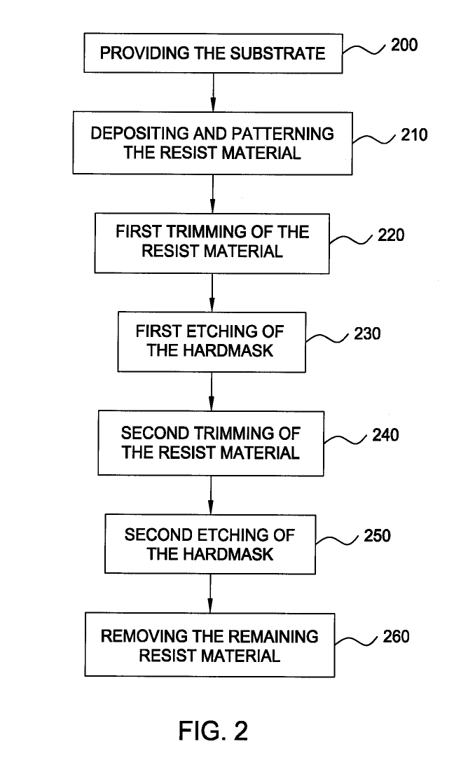

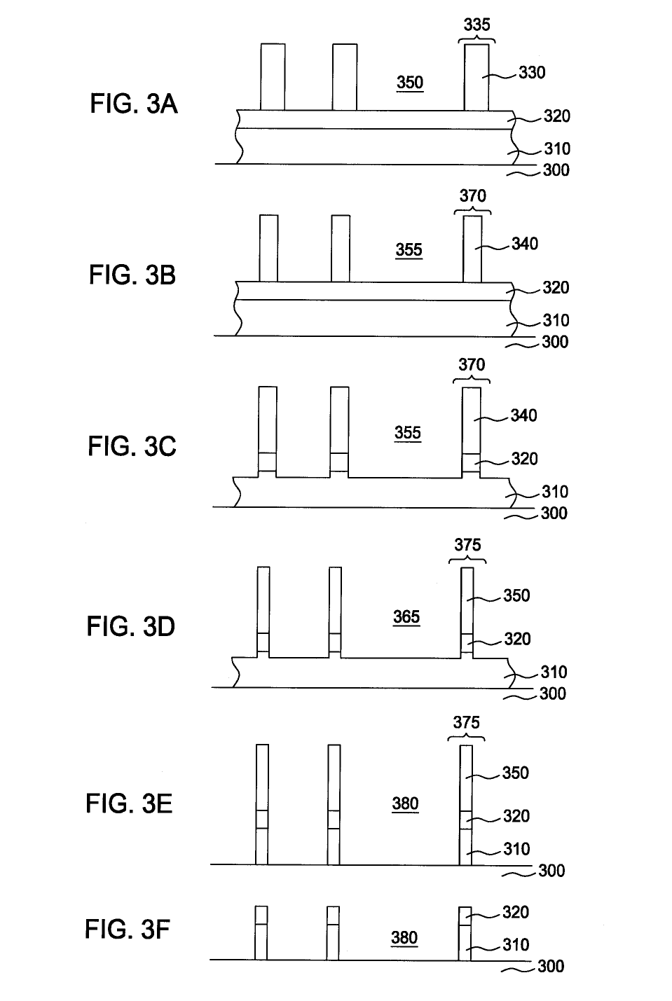

One embodiment of a structure fabricated in accordance with the invention including the resist trimming step is sequentially depicted in a flow chart in FIG. 2 and schematically in FIGS. 3A-3F. The flow chart of FIG. 2 is provided for illustrative purposes and should not be construed as limiting the scope of the invention. FIGS. 3A-3F are cross sectional views of a substrate having the steps 200-260 of the flowchart of FIG. 2 performed thereof. To best understand the invention, the reader should simultaneously refer to FIGS. 2 and 3A-3F. The views in FIGS. 3A-3F relate to individual processing steps that are used to a desired feature definition in a hardmask layer. Sub-processes and lithographic routines (e.g., exposure and development of photoresist, wafer cleaning procedures, and the like) are not shown in FIG. 2 and FIGS. 3A-3F. The images in FIGS. 3A-3F are not depicted to scale and are simplified for illustrative purposes.

A substrate 300 is provided in Step 200 of FIG. 2 and as illustrated in FIG. 3A. The substrate 300 comprises the material to be ultimately etched with feature definitions. The substrate 300 may comprise polysilicon, amorphous silicon, or any other suitable layer in which features are to be etched. A hardmask 310 material, such as a nitride or oxide material including silicon nitride, silicon oxynitride or silicon oxide, is deposited on the substrate 300. An optional anti-reflective coating, or bottom anti-reflecting coating (BARC) layer, formed from any of the organic ARC materials known in the art, using conventional methods known in the art, such as an organic spin-on glass (SOG), is deposited on the hardmask 310. The anti-reflective coating 320 typically has a thickness within the range of about 300 Å about 3000 Å.

A resist material 330, such as a DUV photoresist material is deposited on the substrate. The materials of the substrate 300, hardmask 310, and anti-reflective coating 320 may vary on the features to be formed in a particular material for semiconductor processing. A typical film thickness for such a resist material ranges from about 4000 Å to about 6000 Å. DUV photoresists are available from either JSR® or SHIPLEY®, INC., for example, and not by way of limitation.

The resist material 330 may then be exposed, developed, and patterned at Step 210 to form the pattern resist material 330 with features having an initial width 335 as shown in FIG. 3A. The patterned resist features are conventionally fabricated using a lithographic process when a pattern of the feature to be formed is optically transferred into the layer of photoresist. For example, the photoresist is compared to UV light and unexposed portions of the photoresist are removed by oxygen ashing, while the remaining photoresist retains the pattern. Typically, the areas, or feature definitions 350, formed between the patterned resist features have the critical dimensions (CD) as the feature definitions ultimately etched in the substrate 300. However, optical limitations of the lithographic process may not allow transferring a dimensionally accurate image of a feature into the photoresist layer when a CD of the element is smaller than optical resolution of the lithographic process.

The resist material 330 is then subjected to a resist removal process with resist material 330 preferentially being removed from the sides of the resist features to form resist feature 340 having a first feature width 370 smaller than the initial feature width 335, this process is referred to as trimming, at Step 220 as shown in FIG. 3B. The trimming process allows for forming the resist material 330 to include feature definitions 355 more accurately reflecting the critical dimensions of the feature definitions to be formed in the hardmask and ultimately the underlying substrate. The resist material 330 may have its width reduced, for example, by up to 50%, such as between about 10 and about 30%, of the initial width 335.

The trimming process may include, in one illustrative embodiment, using a plasma comprising hydrogen bromide (HBr) at a flow rate of 3 to 200 sccm, oxygen at a flow rate of 5 to 100 sccm (corresponds to a HBr:O₂ flow ratio ranging from 1:30 to 40:1), carbon tetrafluoride (CF₄), and argon (Ar) at a flow rate of 10 to 200 sccm. The plasma is generated using a plasma power of 200 to about 600 W and a bias power of 15 to 45 W, a wafer pedestal temperature between 0 to 80° C. and a chamber pressure of about 2 to 30 mTorr. The trimming photoresist step 220 is performed for about 20 to about 180 seconds. One photoresist trimming process is performed using HBr at a flow rate of 80 sccm, O₂ at a flow rate of 28 sccm (i.e., a HBr:O₂ flow ratio of about 2.5:1), Ar at a flow rate of 20 sccm, a plasma power of 500 W, a bias power of 0 W, and a wafer pedestal temperature of 65 degrees Celsius at a chamber pressure of 4 mTorr. Further examples of resist trimming are described in co-pending U.S. patent application Ser. No. 11/315,941, filed on Dec. 22, 2005, now published as U.S. Patent Publication No. 2006-0205223, entitled “Line Edge Roughness Reduction Compatible with Trimming.”

A first etching process for the anti-reflective coating 320 and the hardmask 310 material is then performed at Step 230 as shown in FIG. 3C. In one embodiment, as shown in FIG. 3C, the anti-reflective coating 320 and a portion of the hardmask 310 material, for example between about 5% and 50% of the thickness of the hardmask 310 material, are etched. Alternatively, only the anti-reflective coating 320 may be etched in the first etching process. The etching process for the anti-reflective coating 320 and the hardmask 310 material may vary based on the material being etched, and the invention contemplated that any etch process, known or unknown, may be used to etch the respective materials of the anti-reflective coating 320 and the hardmask 310 material.

A second trimming process is then performed on the resist feature 340 to preferentially remove resist material from the sides of the resist feature 340 to form feature definitions 350 having a second feature width 375 smaller than the first feature width 370 at Step 240 as shown in FIG. 3D. The trimming process may also remove portions of the anti-reflective coating 320 and hardmask 310 to include feature definitions 365 more accurately reflecting the critical dimensions of the feature definitions be formed in the substrate. The resist feature 340, with the anti-reflective coating 320 and hardmask 310, may have its width reduced, for example, by up to 50%, such as between about 10% and about 30%, of the first feature width 370.

Process Steps 230 and 240 may be repeated as many times as necessary to produce the desired feature definitions 365 prior to the second hardmasks etching process Step 250.

The remaining hardmask 310 material may then be etched for a second time to the surface of the substrate to form feature definitions 380 at Step 250 as shown in FIG. 3E. The etching process for Step 250 may be the same or a different etching process as used in step 230. The remaining resist material 330 may be removed in an ashing step at Step 260 as shown in FIG. 3F. Generally, the remaining resist removal process is performed using a conventional photoresist stripping process that uses an oxygen-based chemistry, e.g., a gas mixture comprising oxygen and nitrogen. The feature definitions 380 formed in the hardmask 310 may then be transferred into the substrate 300 in a subsequent etch process.

The above described etching and trimming processes, including the ashing step at Step 260, may be performed in-situ using the etching chambers described herein. In situ should be broadly construed and includes, but is not limited to, in a given chamber, such as in a plasma chamber, or in a system, such as an integrated cluster tool arrangement, without exposing the material to intervening contamination environments, such as breaking vacuum between process steps or chambers within a tool. An in situ process typically minimizes process time and possible contaminants compared to relocating the substrate to other processing chambers or areas.

While the foregoing is directed to preferred embodiments of the present invention, other and further embodiments of the invention may be devised without departing from the basic scope thereof, and the scope thereof is determined by the claims which follow.

What is claimed is:

1. A method of processing a substrate, comprising:
depositing a hardmask material on a surface of the substrate;
depositing an anti-reflective coating on the hardmask material;
depositing a resist material on the anti-reflective coating;
patterning the resist material to form a first resist feature having a first width to expose the anti-reflective coating;
etching the anti-reflective coating and a first portion of the hardmask material; and
trimming the resist material to form a second resist feature having a second width less than the first width.

2. The method of claim 1, further comprising:
etching a second portion of the hardmask material to the surface of the substrate; and
removing the resist material.

3. The method of claim 1, wherein the patterning the resist material to form the first resist features having the first width comprises:
patterning the resist material to form resist features having an initial width to expose the anti-reflective coating; and
trimming the resist material to form the first resist features having the first width.

4. The method of claim 1, wherein the hardmask material is selected from the group comprising silicon nitride, silicon oxynitride, and silicon oxide.

5. The method of claim 1, wherein the anti-reflective coating has a thickness between about 300 Å and about 3000 Å.

6. The method of claim 1, wherein the resist material has a thickness between about 4000 Å to about 6000 Å.

7. The method of claim 1, wherein the trimming the resist material to form a second resist feature having a second width less than the first width is performed for a time period between about 20 seconds to about 180 seconds.

8. The method of claim 1, wherein etching the anti-reflective coating and a first portion of the hardmask material comprises etching between about 5% and about 50% of a thickness of the hardmask material.

9. The method of claim 1, further comprising repeating the steps of etching the anti-reflective coating and a first portion of the hardmask material and trimming the resist material to form a second resist feature having a second width less than the first width until a desired width of the second resist is achieved.

10. The method of claim 1, wherein the resist material is a photoresist material.

11. The method of claim 1, wherein trimming the resist material to form a second resist feature having a second width less than the first width comprises forming a plasma comprising hydrogen bromide at a flow rate of 3 sccm to 200 sccm, oxygen at a flow rate of 5 sccm to 100 sccm, carbon tetrafluoride, and argon at a flow rate of 10 to 200 sccm.

12. A method of processing a substrate, comprising:
depositing a hardmask material on a surface of the substrate;
depositing a resist material on the hardmask material;
patterning the resist material to form a first resist feature having a first width to expose the hardmask material;
etching the anti-reflective coating and a first portion of the hardmask material;
trimming the resist material to form a second resist feature having a second width between 10% and 30% less than the first width;
etching a second portion of the hardmask material to the surface of the substrate; and
removing the resist material.

13. The method of claim 12, wherein the hardmask material is selected from the group comprising silicon nitride, silicon oxynitride, and silicon oxide.

14. The method of claim 12, wherein the anti-reflective coating has a thickness between about 300 Å and about 3000 Å.

15. The method of claim 12, wherein the resist material has a thickness between about 4000 Å to about 6000 Å.

16. The method of claim 12, wherein the trimming the resist material to form a second resist feature having a second width less than the first width is performed for a time period between about 20 seconds to about 180 seconds.

17. The method of claim 12, wherein etching the anti-reflective coating and a first portion of the hardmask material comprises etching between about 5% and about 50% of a thickness of the hardmask material.

18. The method of claim 12, further comprising repeating the steps of etching the anti-reflective coating and a first portion of the hardmask material and trimming the resist material to form a second resist feature having a second width less than the first width until a desired width of the second resist is achieved.

19. The method of claim 12, wherein the resist material is a photoresist material.

20. The method of claim 12, wherein trimming the resist material to form a second resist feature having a second width less than the first width comprises forming a plasma comprising hydrogen bromide at a flow rate of 3 sccm to 200 sccm, oxygen at a flow rate of 5 sccm to 100 sccm, carbon tetrafluoride, and argon at a flow rate of 10 to 200 sccm.
